(19) United States
(12) Patent Application Publication
(10) Pub. No.: US 2018/0084645 A1
(43) Pub. Date: Mar. 22, 2018

(54) FIELD DEVICE FOR PROCESS AUTOMATION

(71) Applicant: Endress+Hauser Conducta GmbH+Co. KG, Gerlingen (DE)

(72) Inventors: Björn Haase, Stuttgart (DE); Janos Alvincz, Stuttgart (DE); Christoph Fecker, Stuttgart (DE); Hashem Amro, Stuttgart (DE)

(21) Appl. No.: 15/704,078

(22) Filed: Sep. 14, 2017

(30) Foreign Application Priority Data
Sep. 21, 2016 (DE) 10 2016 117 795.4

(51) Int. Cl. H05K 1/18; H05K 1/02; H05K 3/46

(52) U.S. Cl. CPC H05K 1/18; H05K 1/0203; H05K 3/4691; H05K 1/028; H05K 1/0278; H05K 1/0271

(57) ABSTRACT

The present disclosure relates to a process automation field device having a housing and a printed circuit board, wherein the printed circuit board and housing have at least one common fixation region by which a relative movement of the printed circuit board within the housing is prevented, characterized in that the printed circuit board has at least one opening to compensate for diverging changes in length between the printed circuit board and housing.

### CROSS-REFERENCE TO RELATED APPLICATION

The present application is related to and claims the priority benefit of German Patent Application No. 10 2016 117 795.4, filed on Sep. 21, 2016, the entire contents of which are incorporated herein by reference.

### TECHNICAL FIELD

The present disclosure relates to a field device for process automation comprising a housing and a printed circuit board, wherein a printed circuit board is securely affixed to the housing.

### BACKGROUND

A printed circuit board (PCB) is a carrier for electronic components. It serves for mechanical attachment and electrical connection. Nearly every electronic device contains one or more printed circuit boards. Printed circuit boards consist of electrically insulating material with conductive connections, termed conductor tracks, which are bonded thereto. Fiber-reinforced plastic is conventional as the insulating material. The conductor tracks are generally etched from a thin layer of copper. The thermal expansion coefficient of the plastic is almost precisely adapted to the expansion coefficient of the copper (approximately 17 ppm/K), to avoid so-called delamination during a change in temperature.

This adaptation makes it necessary to use high percentages of fiberglass; the printed circuit board accordingly remains flexible within certain limits, but, practically speaking, cannot be compressed or stretched.

Whereas the thermal expansion coefficient of the printed circuit board material can be adapted to the thermal parameters of copper by means of the ratio between artificial resin and fiberglass reinforcement, this can be accomplished especially, for plastic housings within only narrow limits, with a typical expansion coefficient of 50-100 ppm/K that is significantly higher than that of printed circuit boards.

In process automation especially, for automating chemical processes or process engineering and/or for controlling industrial plants, process-related, installed measuring devices, or so-called field devices, are used. Field devices designed as sensors can, for example, monitor the process measurands such as pressure, temperature, flow, and fill-level, or measurands in liquid and/or gas analysis such as pH, conductivity, concentrations of certain ions, chemical compounds, and/or concentrations or partial pressures of gas.

Process automation field devices generally have a housing and at least one printed circuit board that is affixed in the housing by means of suitable fasteners such as screws, snap-in plastic clips, or plug-in connectors. When configuring the position of the fasteners, it should be taken into account that, generally, the thermal expansion coefficients of the housing and printed circuit board vary, and mechanical stresses can arise from changes in temperature if the printed circuit board is inflexibly affixed within the housing at more than one location.

If different thermal changes in length arise between the housing and the fixation areas at which the printed circuit board is held, appropriate movable compensation elements are needed, such as by an elastically-designed plug-in connector that compensates for the thermally-induced relative movements. This is achieved with plastic clips designed to be slightly flexible that can accommodate changes in length, or by affixing the printed circuit board within the housing at only just one fixation region, and sufficient mobility is ensured at other fixation regions by, for example, using so-called elongated holes or holes which are designed to be larger than the nominal dimensions of the associated screw. In the use of elongated holes, the printed circuit board has been screwed tight at just one position, and any other necessary screw within the elongated hole is affixed to the printed circuit board so that the position of the other screw can move within sufficiently large limits during temperature changes without damage and shift, as it were, in the elongated hole.

A disadvantage of using plug-in connectors as movable compensation elements is that, in the event of a thermal change in length of the printed circuit board relative to the housing, the printed circuit board can slip within the plug-in connector, or the material of the compensation elements can weaken or be destroyed from abrasion under excessive movement. This holds true, especially, when many lines need to be run, or four-pin plug-in connectors are used.

### SUMMARY

The aim of the present disclosure is to provide a process automation field device that is capable of compensating for the diverging changes in length between the printed circuit board and housing, without the position of the printed circuit board changing within the housing.

The aim is achieved by the features of the subject matter of the present disclosure from claim 1 and the derived dependent claims. The subject matter of the present disclosure is a process automation field device including a housing and a printed circuit board, wherein the printed circuit board and housing have at least one common fixation region by means of which a relative movement of the printed circuit board within the housing is prevented, characterized in that the printed circuit board has at least one opening to compensate for diverging changes in length between the printed circuit board and housing.

Thermal stresses are avoided in that the printed circuit board has at least one opening. The system of mechanically affixing the printed circuit board and housing is, consequently, not over-determined.

According to an advantageous development, an inner chamber of the housing is filled at least partially with a potting compound.

According to an advantageous variation, a compressible material such as foam is arranged within the at least one opening so that no potting compound penetrates into the at least one opening.

According to an advantageous design, an elastic material such as foam is arranged within the at least one opening so that no potting material penetrates into the at least one opening.

According to an advantageous embodiment, the dimensions of a gap between the housing and printed circuit board in a section with a large relative movement between the printed circuit board and housing are larger than in a section with a small relative movement between the printed circuit board and housing.

According to an advantageous variation, the printed circuit board is fastened to the housing at at least one fixation region by means of the potting compound.

According to an advantageous development, the printed circuit board is fastened to the housing at at least one of the fixation regions by means of a hard potting compound especially, epoxide.

According to a favorable development, the potting material is cured at a temperature that lies above an operating temperature of the field device.

According to a favorable variation, the printed circuit board has several electrically conductive layers by means of which electrical signals can be transmitted.

According to a favorable embodiment, the at least one opening is designed to be elongated.

According to a favorable embodiment, the printed circuit board has at least two openings that form a meandering structure on the printed circuit board.

### BRIEF DESCRIPTION OF THE DRAWINGS

The present disclosure will be explained in greater detail with reference to the following drawings. In the drawings:

FIG. 1 shows a plan view of a first printed circuit board,

FIG. 2 shows a plan view of a region of a second printed circuit board of an automation field device, and

FIG. 3 shows a longitudinal section of an electronics housing of a field device with a housing and printed circuit board.

### DETAILED DESCRIPTION

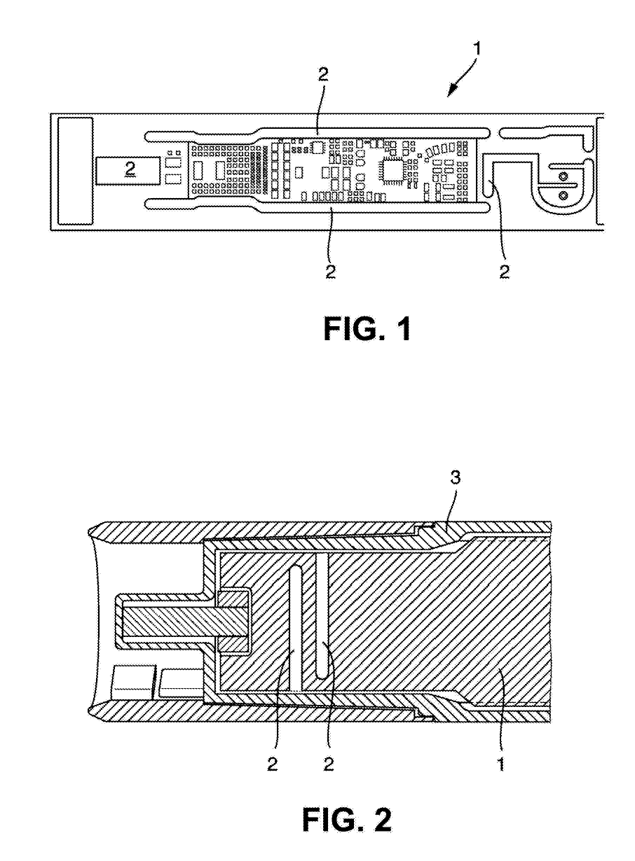

FIG. 1 shows a plan view of a printed circuit board 1 of an automation field device.

In the field of process automation, an explosion-protected electronics housing is frequently necessary. The measures required for explosion protection make it difficult, from the vantage point of thermal stress, to affix printed circuit boards 1 in the housing 3; a primary measure from the state-of-the-art for explosion-protected circuit design consists of filling the housing 3 with plastic potting compound. This makes it possible, for example, to safely electrically insulate energy stores containing sufficient energy for ignition sparks from an environment in which there can be explosive gases or dusts. Routinely, the relevant explosion protection standards require adhesion of the potting compound on the printed circuit board 1 and on the housing 3.

The problematic aspect of affixing the printed circuit board 1 within the housing 3 and the thermal stress that this generates is that, generally, the potting compound not only insulates, but securely glues the housing 3 and printed circuit board 1 to each other at the same time. This causes the potentially problematic over-determination of fixation, and thereby prevents the possibility of thermal compensation. Frequently, casting an assembly also involves the use of plug-in connectors, since the elastic contact elements that are used in that context are glued by the potting compound 12.

Frequently, when potting compound is used, it is no longer possible to establish specific fixation areas and “intentional movement points” such as elongated holes and plug-in connectors.

According to the present disclosure, the problem of thermal stress is solved in that elongated openings 2 in the form of a slot are milled into the printed circuit board 1 at a suitable location. The tensile stress (compressive stress) is converted in this case into a bending of the printed circuit board 1 at the end of a contour of the openings 2. The fact is advantageously exploited here that the printed circuit board 1 is not compressible, yet remains elastic and flexible within certain limits.

By means of the openings 2, the printed circuit board 1 more or less assumes the task of a compensation spring. In the region of the printed circuit board 1 remaining between the openings 2, the required electrical signals can run via conductor paths 11 from a first end of the printed circuit board 1 to a second, opposite end of the printed circuit board 1, without expensive plug-in connectors or cable elements being necessary.

To the extent that several so-called copper layers are available in the interior of the printed circuit board 1, the conductor paths can run redundantly in more than one copper layer, in order to, advantageously, remain reliably functional even in the event of damage to one of, for example, four copper layers from the bending movement.

The openings 2 also solve the problem of the assembly personnel having to mechanically install and place two independent individual parts when using two separate printed circuit boards that move relative to each other with one connecting element (cable/plug-in connector), and thereby eliminate correspondingly high assembly costs.

Likewise, abrasion to plug-in connector contacts caused by electrical connections between two printed circuit board parts that move relative to each other, which leads to long-term failure, is avoided. As another advantage, the addition of slotted contours in printed circuit boards 1 is associated with only minimal costs.

FIG. 2 shows a plan view of a region of a second printed circuit board 1 of an automation field device. The printed circuit board 1 has two elongated openings 2 which form a meandering structure on the printed circuit board 1. Since the printed circuit board 1 is securely affixed within the housing 3, changes in temperature can cause different thermal changes in the length of the housing 3 and printed circuit board 1. Such a movement can, for example, arise from differing thermal expansion of the housing 3 and printed circuit board 1, as will be explained in greater detail below. Differing thermal or otherwise generated movements between the printed circuit board 1 and housing 3 can be compensated for in this manner by means of the elongated openings 2. Due to the openings 2, the printed circuit board 1 can, to a certain extent, be compressed in the longitudinal direction, stretched, or subjected to a certain amount of torsion in this region, without being destroyed.

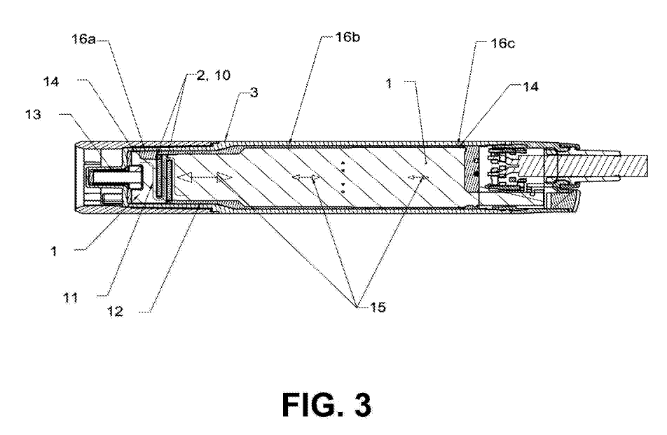

FIG. 3 shows a longitudinal section of an electronics housing of a field device with a housing 3 and printed circuit board 1. The housing 3 is designed as an elongated hollow cylinder (the sensor which is a component of the field device is not visible in FIG. 3).

In the area on the left in FIG. 3, one can see arranged on the printed circuit board 1 a coil 13, which is inserted in a cylindrical spike arranged in the end of the housing 3, and which forms the left end of the housing 3. The coil 13 is the primary side of an inductively coupling, plug-in connection with a secondary side that is complementary to the primary side and connected to the sensor. By means of this plug-in connection, the sensor can be connected to the electronics housing shown in FIG. 3.

The printed circuit board 1 is arranged within the housing 3 and has two fixation regions 14 with the housing 3. A first fixation region 14 is located in the proximity of a coil 13, whereas the second fixation region 14 is located on the opposite end of the printed circuit board 1, and a relatively large longitudinal spacing of, for example, 150 mm accordingly results between them. Fixation can occur by rigid gluing, by potting compound, by screws, or by other construction methods.

If the printed circuit board 1 and housing 3 are rigidly affixed to each other at the fixation regions 14 for example, at room temperature the printed circuit board 1 seeks to expand as the temperature increases at a first temperature coefficient such as 18 ppm/K, and the housing 3 seeks to expand at a second temperature coefficient such as 80 ppm/K, which differs from the first temperature coefficient. A noticeable divergence results especially, when plastic is used in the housing 3.

If the spacing of the fixation regions 14 is, for example, 150 mm, the printed circuit board 1 expands between these fixation regions 14, at a temperature increase of 100° C., about 1 mm less than the surrounding housing 3. Such temperature changes can, for example, be easily caused by the process temperatures during use, or in sterilization procedures.

Since the printed circuit board 1 and the housing 3 are rigidly affixed to each other at the fixation regions 14, the temperature change, without the meandering openings 2, would engender mechanical stress at the fixation regions 14. Without the openings 2, in the examples given, either the housing 3 would have to be compressed by about 1 mm in the longitudinal direction, or alternatively, the printed circuit board 1 would have to be stretched by about 1 mm. If this is not possible, the printed circuit board 1 would break off at one of the fixation regions 14, or the weaker of the two components (housing 3 and printed circuit board 1) would be destroyed.

The openings 2 define a location at which the divergent changes in length can be compensated for free of destruction. The printed circuit board 1 remains affixed at both ends in the region of the fixation regions 14, even under temperature changes. If the housing 3 expands more than the printed circuit board 1, a relative movement between the housing 3 and printed circuit board 1 results in the interior of the housing 3. The thermal shifts between the housing 3 and printed circuit board 1 are schematically sketched by arrows 15 of different sizes. There is no relative movement between the printed circuit board 1 and housing 3 in the fixation regions 14, and, as the spacing between the fixation regions 14 increases, there is an increasing thermal shift. In the region of the openings 2, a maximum relative movement is achieved and converted into an elastic bending of the remaining thin, meanderingly-designed openings 2 of the printed circuit board 1. In other words, the printed circuit board 1 is specifically weakened mechanically by the openings 2, so that the thermally required longitudinal compensation can occur there without disruption.

The elongated openings 2 in the printed circuit board 1 also make it possible for the housing 3 to be completely fillable with potting compound 12 for reasons of explosion protection, for example. In this case, a foam body 10 is, advantageously, inserted into the elongated openings 2. The size of the slotted opening 2 and dimensions of the foam body 10 are such that the foam body 10 is secured by clamping after being inserted into the openings 2 and cannot fall out by itself during the assembly of the device. When using a closed-pore foam body 10, the foam body 10 is not saturated by a liquid potting compound, and retains its compressibility even after the potting compound 12 cures.

When the printed circuit board 1 is inserted into the cylindrical housing 3, first, a foam body 10 is inserted into the housing 3. Then, a potting compound 12 is added. This encloses the printed circuit board 1 and its components and adheres to the inside of the housing 3 and the printed circuit board 1, and fills the gap 16 that arises between the printed circuit board 3 when the printed circuit board 1 is inserted in the housing 3.

By using the foam body 10, the spring effect of the openings 2 is retained even when the electronics are potted in the housing 3. When the printed circuit board 1 contracts in the region of the elastic openings 2, the first part of the printed circuit board 1 accordingly moves relative to the housing 3 at this position.

Consequently, the outer contour of the printed circuit board 1 and the inner contour of the housing 3 are dimensioned such that, on both sides of the slotted openings 2, a sufficiently large gap 16 that is filled with potting compound 12 remains between the housing 3 and printed circuit board 1. Since the printed circuit board 1 moves relative to the housing 3 at the gap 16 (the amount of movement is sketched by schematic arrows 15), an elastic potting compound 12 can bring about a compensation between the housing 3 and printed circuit board 1 at this location when the gap 16 is sufficiently large, without the printed circuit board 1 tearing off and thereby possibly being destroyed.

The dimensions of the gap 16 filled with potting compound 12 are advantageously dimensioned to depend upon the thermal movement arising between the printed circuit board 1 and housing 3.

A first section 16a of the gap 16 is relatively large, since a large thermal relative movement between the housing 3 and printed circuit board 1 is anticipated in this section 16a. A third section 16c of the gap 16 is relatively small, since a small thermal relative movement between the housing 3 and printed circuit board 1 is anticipated in this section 16c.

The aforementioned considerations apply not only to the dimensioning of the gap between the printed circuit board and housing wall, but also to the gap between the electronic components placed upon the printed circuit board 1 (such as the coil 13) and the housing wall, since these also move with the printed circuit board 1.

In the exemplary embodiment in FIG. 3, the dimensions of the gap 16 are adapted stepwise in three levels: first, second, and third sections 16a, 16b, 16c. However, a trapezoidal gap 16 with a continuous enlargement of the gap dimensions, or other suitable shapes of the gap 16, are also possible. Especially in regions where there are pronounced relative movements between the housing 3 and printed circuit board 1, it is then necessary to reduce the width of the printed circuit board 1, in order to prevent the potting compound 12 from breaking off by a compound-filled gap 16 dimensioned to be sufficiently large.

The use, between the printed circuit board 1 and housing 3, of a gap 16 that is not evenly filled with potting compound 12 has, moreover, the advantage that, by varying the dimensions of gap the between the components bonded by the potting compounds 12, the desired fixation regions 14 are implicitly also defined. Accordingly, with a small gap 16, adhesion is secure, whereas, with a large gap 16, a certain amount of movement is permitted within the limits of the elasticity of the potting compound 12.

Given a gap 16 with small dimensions, the printed circuit board 1 and housing 3 are securely bonded by the potting compound 12. In the section 16a with a large gap 16, the potting compound allows a greater degree of movement between the housing 3 and printed circuit board 1.

Advantageously, an elastically configured potting compound especially, one based upon so-called silicones or polyurethanes is used, to allow the potting compound 12 to break off under relative movements between the housing 3 and printed circuit board 1 even when the filled gaps 16 are relatively small, due to the advantageous features of elasticity and adhesion to housings 3 made of plastic and the printed circuit boards 1 of these materials. This class of materials also has the advantage that it typically manifests low volume shrinkage while curing and is therefore particularly advantageous for the described application.

In one advantageous embodiment, the printed circuit board 1 and/or housing 3 are sprayed or treated with an adhesion promoter or lacquer before assembly, to improve the adhesion of the potting compound, even under the emerging thermal stress.

In one advantageous embodiment, at least one of the fixation regions 14 is so defined that more than one potting material is used, and, in the region of the fixation regions 14 that are desired, or may be constructively desired, from amongst certain locations, exactly at one defined location, a hard, less elastic potting material is used. Accordingly, assemblies of the printed circuit board 1, at an end, opposite the coil 13, of the printed circuit board 1 at the fixation region 14, can be potted at a length of, for example, 5 mm with a hard potting material, e.g., one based upon epoxide resin, and mechanically affixed. The assembly in this case is, for example, potted in two stages. The hard, second potting material can also advantageously assume other structural tasks such as strain relief of cables inserted into the housing 3.

In another advantageous embodiment, the first and, optionally, second potting materials are cured and/or added to the housing 3 at or slightly above 0-15° C. above the maximum specified temperature for operating or storing the field device. This can, advantageously, prevent an expansion in volume of the potting compound 12 itself from generating additional, mechanical, compressive stress after the potting compound cures, since only volume shrinkage and, hence, tensile stress at most can then arise. This advantageously exploits the fact that a cured potting compound especially, polyurethanes or silicones is flexible to a certain extent after curing (tensile stress remains possible), but is almost incompressible (compressive stress would cause the housing 3 to “burst”).

By suitably selecting a (high) temperature at the time of curing, the problem of compressive stress is overcome, since volume shrinkage of the potting compound 12 can occur at all of the relevant operating temperatures of the device, and the divergence of thermal expansion coefficients between the potting compound, on the one hand, and housing 3 and printed circuit board 1, on the other, can be compensated for by the elasticity of the potting compound 12. In addition, advantageously reduced process cycle times result from the feature of curing at around the highest specified temperature, since an increase in temperature is generally associated with reduced curing times. This thus advantageously reduces production times and, thus, production costs.

1. A field device for process automation, comprising:
a housing having an inner chamber; and
a printed circuit board disposed within the inner chamber, wherein the printed circuit board and the housing have at least one common fixation region which prevents a relative movement of the printed circuit board within the inner chamber,
wherein the printed circuit board has at least one opening to compensate for divergent changes in length between the printed circuit board and housing.

2. The field device according to claim 1, wherein the inner chamber of the housing is filled at least partially with a potting compound.

3. The field device according to claim 2, wherein a compressible material is disposed within the at least one opening such that no potting compound penetrates into the at least one opening.

4. The field device according to claim 1, wherein the circuit board is disposed such that a gap between the housing and the printed circuit board in a section with a large relative movement between the printed circuit board and the housing is larger than a gap between the housing and the printed circuit board in a section with a small relative movement between the printed circuit board and housing.

5. The field device according to claim 2, wherein the printed circuit board is fastened to the housing at at least one fixation region by the potting compound.

6. The field device according to claim 5, wherein the printed circuit board is fastened to the housing at at least one of the fixation regions by a hard potting compound.

7. The field device according to claim 2, wherein the potting material has a curing temperature greater than an operating temperature of the field device.

8. The field device according to claim 1, wherein the printed circuit board has several electrically conductive layers by which electrical signals can be transmitted.

9. The field device according to claim 1, wherein the at least one opening is elongated.

10. The field device according to claim 1, wherein the printed circuit board has at least two openings which form a meandering structure on the printed circuit board.

11. The field device according to claim 6, wherein the hard potting compound is epoxide.
